(19) United States
(12) Patent Application Publication
(10) Pub. No.: US 2025/0221239 A1
(43) Pub. Date: Jul. 3, 2025

(54) DISPLAY DEVICE

(71) Applicant: LG Display Co., Ltd., Seoul (KR)

(72) Inventors: YoungNam LIM, Seoul (KR); SeHong PARK, Paju-si (KR); Hyeonhye YU, Seoul (KR)

(73) Assignee: LG Display Co., Ltd., Seoul (KR)

(21) Appl. No.: 18/892,846

(22) Filed: Sep. 23, 2024

(30) Foreign Application Priority Data
Dec. 28, 2023 (KR) 10-2023-0195552

(51) Int. Cl. H10K 59/80; H10K 59/122

(52) U.S. Cl. CPC H10K 59/80515; H10K 59/122; H10K 59/80518; H10K 59/878

(57) ABSTRACT

A display device may include: an over coating layer having a base portion and a protrusion; an anode; and a bank. The anode may include first, second and third parts. An edge of the second part may form a first polygon on the plane. When a virtual second polygon which is congruent with the first polygon while sharing the center with the first polygon and is disposed with a smaller area than the first polygon on the plane is defined, the first part may include a protruding portion formed by an edge disposed outside of the second polygon on the plane and a dented portion formed by an edge disposed inside of the second polygon on the plane. The third part may include a concave inclined portion corresponding to the protruding portion and a convex inclined portion corresponding to the dented portion.

### CROSS-REFERENCE TO RELATED APPLICATIONS

This application claims the benefit of and priority to Korean Patent Application No. 10-2023-0195552 filed on Dec. 28, 2023, in the Korean Intellectual Property Office, the entire contents of which are incorporated herein by reference for all purposes, as if fully ser forth herein.

### BACKGROUND

### 1. Technical Field

The present disclosure relates to a display device, and more particularly, for example, without limitation, to a display device which increases a light extraction efficiency of a light emitting diode for the same area.

### 2. Description of the Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, a display device is a self-emitting display device so that a separate light source is not necessary, which is different from a liquid crystal display device. Therefore, the display device may be manufactured to have a light weight and a thin-thickness. Further, since the light emitting display device is driven at a low voltage so that it is advantageous not only in terms of power consumption, but also in terms of color implementation, a response speed, a viewing angle, a contrast ratio (CR). Therefore, it is expected to be utilized in various fields.

The description provided in the background section should not be assumed to be prior art merely because it is mentioned in or associated with the background section. The background section may include information that describes one or more aspects of the subject technology.

### SUMMARY

An aspect to be achieved by the present disclosure is to provide a display device with high efficiency and low power which is capable of improving a luminous efficiency of an organic light emitting diode using a side mirror type anode.

Another aspect to be achieved by the present disclosure is to provide a display device with high efficiency and low power which is capable of increasing a light extraction efficiency of a light emitting diode for the same area.

Aspects of the present disclosure are not limited to the above-mentioned aspects, and other aspects, which are not mentioned above, can be clearly understood by those skilled in the art from the following descriptions.

According to an aspect of the present disclosure, a display device includes a substrate, a plurality of sub-pixels, an over coating layer which is disposed on the substrate and includes a base portion and a protrusion which is disposed on the base portion and has an inclined side surface; an anode which is disposed so as to correspond to each of the plurality of sub-pixels and cover parts of the base portion and the protrusion; and a bank disposed on a part of the anode. The anode includes a first part which is disposed on a top surface of the base portion and is exposed from the bank; a second part which is disposed on the top surface of the base portion and is covered by the bank; and a third part disposed on a side surface of the protrusion, an edge of the second part forms a first polygon on the plane. When a virtual second polygon which is congruent with the first polygon while sharing the center with the first polygon and is disposed with a smaller area than the first polygon on the plane is defined, the first part includes a protruding portion which is formed by an edge disposed at the outside more than the second polygon on the plane and a dented portion which is formed by an edge disposed inside more than the second polygon on the plane, an area of the protruding portion and an area of the dented portion are equal to each other on the plane, and the third part includes a concave inclined portion which corresponds to the protruding portion and has a concave inclined surface and a convex inclined portion which corresponds to the dented portion and has a convex inclined surface.

Other detailed matters of the example embodiments are included in the detailed description and the drawings.

According to one or more aspects of the present disclosure, the light extraction efficiency of the light emitting display device may be improved using a side mirror type anode and power consumption may be improved.

According to one or more aspects of the present disclosure, the light extraction efficiency of the light emitting diode for the same area may be increased by increasing only a length of a boundary line while maintaining an area of the emission area.

The effects according to the present disclosure are not limited to the contents described above, and more various effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other aspects, features and other advantages of the present disclosure will be more clearly understood from the following detailed description taken in conjunction with the accompanying drawings, in which:

FIG. 1 is a plan view of a display device according to an example embodiment of the present disclosure;

FIG. 2 is an enlarged plan view of an area A of FIG. 1;

FIG. 3 is a cross-sectional view of a display device taken along line B-B′ of FIG. 2;

FIG. 4 is a cross-sectional view of a display device taken along line C-C′ of FIG. 2;

FIG. 5 is a plan view of a display device according to another example embodiment of the present disclosure;

FIG. 6 is a cross-sectional view of a display device taken along line D-D′ of FIG. 5;

FIG. 7 is a plan view of a display device according to still another example embodiment of the present disclosure;

FIG. 8 is a plan view of a display device according to still another example embodiment of the present disclosure; and

FIG. 9 is a plan view of a display device according to still another example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure. Further, the present disclosure is only defined by scopes of claims.

The shapes (e.g., sizes, lengths, widths, heights, thicknesses, locations, radii, diameters, and areas), ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘consist of used herein are generally intended to allow other components to be added unless the terms are used with the term ‘only’. Any references to singular may include plural unless expressly stated otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Components are interpreted to include an ordinary error range even if not expressly stated. As an example, the term “equal to” or “the same as” used herein may contain the case where the compared items are slightly different from each other. Any implementation described herein as an “example” is not necessarily to be construed as preferred or advantageous over other implementations.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

The terms, such as “below,” “lower,” “above,” “upper” and the like, may be used herein to describe a relationship between element(s) as illustrated in the drawings. It will be understood that the terms are spatially relative and based on the orientation depicted in the drawings.

In describing a time relationship, for example, when the temporal order is described as, for example, “after,” “subsequent,” “next,” and “before,” a case which is not continuous may be included unless a more limiting term, such as “just,” “immediate(ly),” or “direct(ly)” is used.

Although the terms “first,” “second,” “A,” “B,” “(a),” and “(b),” and the like are used for describing various components, these components are not confined by these terms. These terms are merely used for distinguishing one component from the other components. Therefore, a first component to be mentioned below may be a second component in a technical concept of the present disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Like reference numerals generally denote like elements throughout the specification.

A size and a thickness of each component illustrated in the drawing are illustrated for convenience of description, and the present disclosure is not limited to the size and the thickness of the component illustrated.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to accompanying drawings.

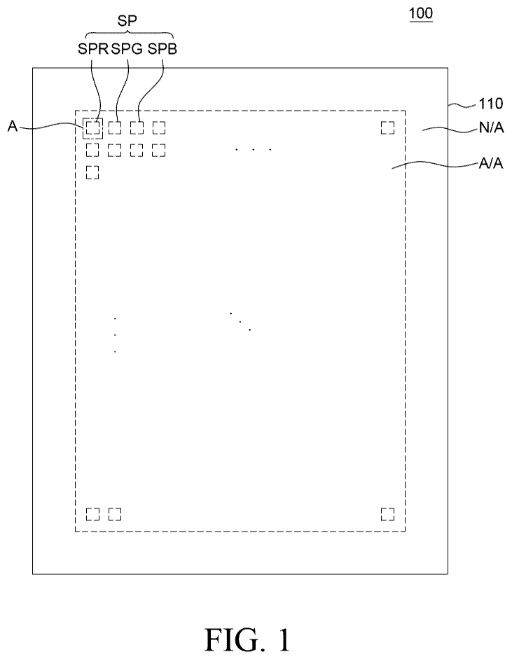

FIG. 1 is a plan view of a display device according to an example embodiment of the present disclosure.

Referring to FIG. 1, the display device 100 includes a substrate 110. The display device 100 may be implemented as a top emission type display device, but is not limited thereto. As an example, the display device 100 may be implemented as a bottom emission type display device, or a dual emission type display device, but is not limited thereto.

The substrate 110 is a substrate which supports and protects a plurality of components of the display device 100. The substrate 110 may be formed of a rigid material or a flexible material. As an example, the substrate 110 may be formed of a glass or a plastic material having flexibility, but is not limited thereto. When the substrate 110 is formed of a plastic material, for example, the substrate may be formed of polyimide (PI), polyethylene terephthalate (PET), polycarbonate (PC), acrylonitrile-butadiene-styrene copolymer (ABS), etc., but it is not limited thereto.

The substrate 110 includes an active area A/A and a non-active area N/A.

The active area A/A is an area in which an image is displayed in the display device 100 and a display element and various driving elements for driving the display element may be disposed in the active area A/A. For example, the display element may be configured by a light emitting diode including a first electrode, an organic layer, and a second electrode. Further, various driving elements for driving the display element, such as transistors, capacitors, or wiring lines may be disposed in the active area A/A.

A plurality of sub-pixels SP may be included in the active area A/A. The sub-pixel SP is a minimum unit which configures a screen and each of the plurality of sub-pixels SP may include a light emitting diode and a driving circuit. The plurality of sub-pixels SP may emit light having different wavelengths, respectively. As an example, the plurality of sub-pixels may include first to third sub-pixels which emit different color light. For example, the plurality of sub-pixels SP may include a red sub-pixel SPR which is a first sub-pixel, a green sub-pixel SPG which is a second sub-pixel, and a blue sub-pixel SPB which is a third sub-pixel. Further, the plurality of sub-pixels SP may further include a white sub-pixel. Embodiments are not limited thereto. As an example, sub-pixels of other colors such as cyan, magenta, or yellow, etc. may be alternatively or additionally included. As an example, the plurality of sub-pixels may include more than three sub-pixels which emit different color light.

The driving circuit of the sub-pixel SP is a circuit for controlling the driving of the light emitting diode. For example, the driving circuit may be configured to include a transistor and a capacitor, but is not limited thereto.

The non-active area N/A is an area where no image is displayed and various components for driving the plurality of sub-pixels SP disposed in the active area A/A may be disposed in the non-active area N/A. For example, a driving IC which supplies a signal for driving the plurality of sub-pixels SP, a flexible film, and the like may be disposed, but is not limited thereto.

The non-active area N/A may be an area which encloses the active area A/A as illustrated in FIG. 1. However, the present disclosure is not limited thereto. For example, the non-active area N/A may be an area extending from the active area A/A. As an example, the non-active area N/A may be adjacent to the active area A/A. As an example, the non-active area N/A may partially or fully surround the active area A/A. As an example, at least a portion of the non-active area N/A may be invisible form a front side of the display device, for example, by being bent toward a rear side of the display device, but is not limited thereto.

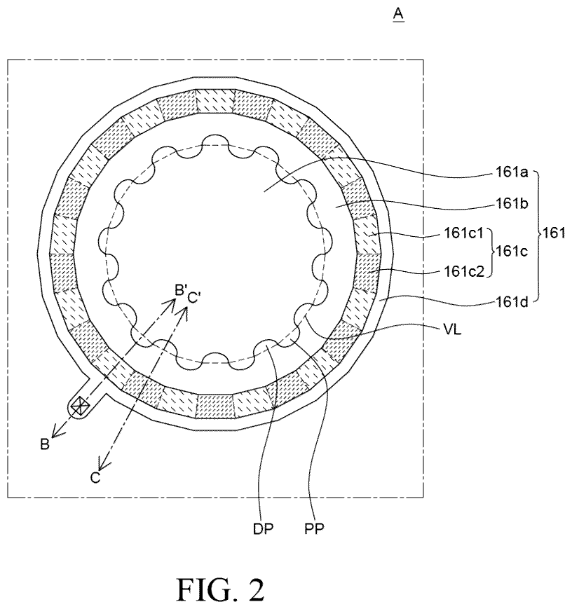

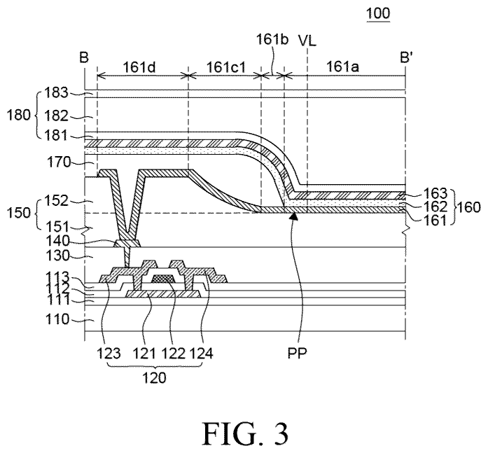

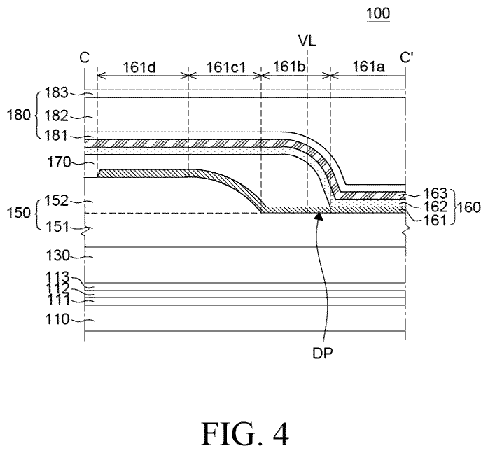

FIG. 2 is an enlarged plan view of an area A of FIG. 1. FIG. 3 is a cross-sectional view of a display device taken along line B-B′ of FIG. 2. FIG. 4 is a cross-sectional view of a display device taken along line C-C′ of FIG. 2. For the convenience of description, in FIG. 2, only a first electrode 161 disposed in one sub-pixel SPR, among various components of the display device 100, is illustrated. FIG. 3 is a cross-sectional view for an area in which a protruding portion PP and a concave inclined portion 161c1 of the first electrode 161 are disposed and FIG. 4 is a cross-sectional view for an area in which a dented portion DP and a convex inclined portion 161c2 of the first electrode 161 are disposed. In the meantime, in FIG. 2, for the convenience of description, the concave inclined portion 161c1 and the convex inclined portion 161c2 are illustrated with different hatchings, but the concave inclined portion 161c1 and the convex inclined portion 161c2 may be integrally disposed using the same material. However, they are not limited thereto. As an example, the concave inclined portion 161c1 and the convex inclined portion 161c2 may be disposed using different materials, without being limited thereto.

Referring to FIGS. 2 to 4, the display device 100 includes a substrate 110, a transistor 120, a first over coating layer 130, an auxiliary electrode 140, a second over coating layer 150, a light emitting diode 160, a bank 170, and an encapsulation unit 180. Embodiments are not limited thereto. As an example, one or more of the above-mentioned components may be omitted, and/or one or more additional components may be further included.

A buffer layer 111 is disposed on the substrate 110. The buffer layer 111 may serve to improve adhesiveness between layers formed on the buffer layer 111 and the substrate 110 and block alkali components leaked from the substrate 110. The buffer layer 111 may be formed as a single layer of silicon nitride (SiNx) or silicon oxide (SiOx) or a multiple layer of silicon nitride (SiNx) and silicon oxide (SiOx), but is not limited thereto. The buffer layer 111 is not an essential component and may be omitted based on a type or a material of the substrate 110 and a structure and a type of a transistor 120.

The transistor 120 is disposed on the buffer layer 111. The transistor 120 may be used as a driving element which drives the light emitting diode 160 of the active area A/A. The transistor 120 includes an active layer 121, a gate electrode 122, a source electrode 123, and a drain electrode 124. The transistor 120 illustrated in FIG. 2 is a driving transistor and is a top gate type thin film transistor in which the gate electrode 122 is disposed above the active layer 121. However, it is not limited thereto and the transistor 120 may be implemented as a bottom gate type transistor.

The active layer 121 is disposed on the buffer layer 111. The active layer 121 is an area in which a channel is formed when the transistor 120 is driven. The active layer 121 may be formed of an oxide semiconductor, and amorphous silicon (a-Si) semiconductor, a polycrystalline silicon (poly-Si) semiconductor, a compound semiconductor or an organic semiconductor, without being limited thereto.

A gate insulating layer 112 is disposed on the active layer 121. The gate insulating layer 112 is a layer for electrically insulating the gate electrode 122 from the active layer 121 and may be formed of an insulating material. For example, the gate insulating layer 112 may be formed as a single layer of silicon nitride (SiNx) or silicon oxide (SiOx) which is an inorganic material or a multiple layer of silicon nitride (SiNx) or silicon oxide (SiOx), but it is not limited thereto.

In the gate insulating layer 112, a contact hole through which the source electrode 123 and the drain electrode 124 are in contact with a source area and a drain area of the active layer 121, respectively, is formed. The gate insulating layer 112 may be formed on the entire surface of the substrate 110 as illustrated in FIG. 2, or patterned, for example, to have the same width as or a larger width than the gate electrode 122 or the active layer 121, but is not limited thereto.

The gate electrode 122 is disposed on the gate insulating layer 112. The gate electrode 122 is disposed on the gate insulating layer 112 so as to overlap a channel region of the active layer 121. The gate electrode 122 may be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

An interlayer insulating layer 113 is disposed on the gate electrode 122. The interlayer insulating layer 113 may be formed as a single layer of silicon nitride (SiNx) or silicon oxide (SiOx) which is an inorganic material or a multiple layer of silicon nitride (SiNx) or silicon oxide (SiOx), but it is not limited thereto. In the interlayer insulating layer 113, a contact hole through which the source electrode 123 and the drain electrode 124 are in contact with the source region and the drain region of the active layer 121, respectively, is formed.

The source electrode 123 and the drain electrode 124 are disposed on the interlayer insulating layer 113. The source electrode 123 and the drain electrode 124 are disposed on the same layer to be spaced apart from each other, but is not limited thereto. The source electrode 123 and the drain electrode 124 are electrically connected to the active layer 121 through the contact holes of the gate insulating layer 112 and the interlayer insulating layer 113. The source electrode 123 and the drain electrode 124 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

In FIG. 3, only a driving transistor, among various transistors 120 included in the display device 100, is illustrated, but other transistors such as a switching transistor may also be disposed.

The first over coating layer 130 is disposed on the interlayer insulating layer 113 and the transistor 120. The first over coating layer 130 is an insulating layer which protects the transistor 120 and planarizes an upper portion of the transistor 120. A contact hole which exposes the source electrode 123 of the transistor 120 is formed on the first over coating layer 130. Even though in FIG. 3, it is illustrated that a contact hole which exposes the source electrode 123 is formed on the first over coating layer 130, it is not limited thereto. For example, a contact hole which exposes the drain electrode 124 may be formed on the first over coating layer 130.

The first over coating layer 130 may be formed of one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

As an example, a passivation layer which covers the interlayer insulating layer 113 and the transistor 120 may be further disposed below the first over coating layer 130. The passivation layer may be formed as a single layer of silicon nitride (SiNx) or silicon oxide (SiOx) or a multiple layer of silicon nitride (SiNx) or silicon oxide (SiOx), but it is not limited thereto. As an example, the passivation layer may be omitted depending on the design.

The auxiliary electrode 140 is disposed on the first over coating layer 130. The auxiliary electrode 140 may serve to electrically connect the transistor 120 and the light emitting diode 160. The auxiliary electrode 140 is electrically connected to the source electrode 123 of the transistor 120 through a contact hole formed in the first over coating layer 130. The auxiliary electrode 140 may be formed of a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof. As an example, the auxiliary electrode 140 may be omitted depending on the design. In this case, the light emitting diode 160 may be directly connected to the source electrode 123 of the transistor 120, without being limited thereto.

The second over coating layer 150 is disposed on the first over coating layer 130. The second over coating layer 150 is an insulating layer for planarizing upper portions of the first over coating layer 130 and the auxiliary electrode 140. A contact hole which exposes the auxiliary electrode 140 is formed on the second over coating layer 150.

The second over coating layer 150 may be formed of one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

The second over coating layer 150 includes a base portion 151 and a plurality of protrusions 152. As illustrated in FIG. 3, the base portion 151 and the plurality of protrusions 152 may be integrally formed. For example, the base portion 151 and the plurality of protrusions 152 are formed of the same material to be simultaneously formed by the same process, for example, by a mask process, but are not limited thereto. As an example, the second over coating layer 150 may include a base portion 151 and a plurality of protrusions 152 in a vertical direction. As an example, the base portion 151 and the plurality of protrusions 152 may be formed of different materials, but are not limited thereto.

The base portion 151 is disposed on the first over coating layer 130. As an example, a top surface of the base portion 151 has a surface parallel to the substrate 110, but are not limited thereto. Therefore, as an example, a step generated due to components disposed therebelow may be planarized by the base portion 151.

The plurality of protrusions 152 is disposed on the base portion 151. The plurality of protrusions 152 is integrally formed with the base portion 151 to protrude from the base portion 151. However, it is not limited thereto and the plurality of protrusions 152 may be formed separately from the base portion 151. As an example, after forming the base portion 151 with a flat top surface, the plurality of protrusions 152 may be separately formed on the top surface of the base portion 151. As an example, top surfaces of the plurality of protrusions 152 may be smaller than bottom surfaces, but is not limited thereto.

Each of the plurality of protrusions 152 includes a top surface and a side surface. The top surface of the protrusion 152 is a surface located on an uppermost portion of the protrusion 152 and may be a surface substantially parallel to the base portion 151 or the substrate 110. The side surface of the protrusion 152 may be a surface which connects the top surface of the protrusion 152 and the base portion 151. As an example, at least one of or all of the side surfaces of the plurality of protrusions 152 may be inclined with respect to the base portion 151.

The light emitting diode 160 is disposed on the second over coating layer 150.

The light emitting diode 160 includes a first electrode 161 which is electrically connected to the source electrode 123 of the transistor 120, an organic layer 162 disposed on the first electrode 161, and a second electrode 163 formed on the organic layer 162.

The first electrode 161 is disposed so as to correspond to each of the plurality of sub-pixels SP. The first electrode 161 is disposed so as to cover the base portion 151 and at least a portion of the plurality of protrusions 152. The first electrode 161 may be disposed along shapes of the base portion 151 and the plurality of protrusions 152 of the over coating layer. Specifically, the first electrode 161 may be disposed on the top surface of the base portion 151 in which the protrusion 152 is not disposed and side surfaces of the plurality of protrusions 152. As an example, the first electrode 161 is disposed along the shapes of the base portion 151 and the protrusions 152. Further, as an example, the first electrode 161 may also be formed on the side surface and a partial area of the top surface of the plurality of protrusions 152.

The first electrode 161 may be an anode of the light emitting diode 160. The first electrode 161 is electrically connected to the auxiliary electrode 140 through the contact hole which is formed on the second over coating layer 150. The first electrode 161 may be electrically connected to the source electrode 123 of the transistor 120 through the auxiliary electrode 140. However, the first electrode 161 may be configured to be electrically connected to the drain electrode 124 of the transistor 120 depending on a type of the transistor 120 and a design manner of the driving circuit.

Each of the plurality of sub-pixels SP includes an emission area and a non-emission area which partially or fully encloses the emission area. The first electrode 161 includes a first part 161a, a second part 161b, a third part 161c, and a fourth part 161d. At this time, the emission area and the non-emission area may be defined by each part of the first electrode 161.

For example, the emission area includes a first emission area and a second emission area which encloses the first emission area and the non-emission area includes a first non-emission area between the first emission area and the second emission area and a second non-emission area which encloses the second emission area. At this time, the first emission area may correspond to the first part 161a, the first non-emission area may correspond to the second part 161b, the second emission area may correspond to the third part 161c, and the second non-emission area may correspond to the fourth part 161d.

The first part 161a is disposed on the top surface of the base portion 151 and a top surface of the first electrode 161 is exposed from the bank 170. The first part 161a may be a part corresponding to an area in which a part of light emitted from the organic layer 162 in the sub-pixel SP is extracted to the outside of the display device 100 via the organic layer 162 and the second electrode 163.

Referring to FIG. 2, the first part 161a may include a protruding portion PP and a dented portion DP.

The protruding portion PP is a portion whose area is increased toward the outside of the first part 161a on the plane and the dented portion DP is a portion whose area is decreased toward the inside of the first part 161a on the plane. As an example, an area of the protruding portion PP and an area of the dented portion DP are substantially equal to each other, or may be different from each other. As an example, the first part 161a is disposed to have a portion whose area is inwardly reduced, with the same area as the portion whose area is outwardly increased on the plane. For example, the planar shape of the first part 161a may be a plurality of circular or curved saw teeth as illustrated in FIG. 2, but is not limited thereto. As an example, with respect to a reference line from which the protruding portion PP protrudes and the dented portion DP is dented, the protruding portion PP and the dented portion DP may have the same shape, and/or may have the same area. Embodiments are not limited thereto. As an example, with respect to the reference line, the protruding portion PP and the dented portion DP may have different shapes, and/or may have different areas.

For example, a planar shape of the second part 161b which encloses the first part 161a has a polygonal shape and a virtual polygon VL which is congruent with the polygonal shape of the second part 161b while sharing the center with the polygonal shape of the second part 161b on the plane and is disposed with a smaller area than the polygonal shape of the second part 161b is defined. In this case, the protruding portion PP is a portion formed by edges of the first part 161a disposed at the outside of the virtual polygon VL and the dented portion DP is a portion formed by edges of the first part 161a disposed at the inside of the virtual polygon VL. That is, the protruding portion PP is a portion whose area is increased from the virtual polygon VL and the dented portion DP is a portion whose area is reduced from the virtual polygon VL. An area of the protruding portion PP and an area of the dented portion DP may be equal to each other. Therefore, as an example, on the plane, the same area of the first part 161a is increased or decreased so that finally, the first part 161a including the protruding portion PP and the dented portion DP may have the same area as the virtual polygon VL. Embodiments are not limited thereto. As an example, the area of the protruding portion PP and the area of the dented portion DP may be different from each other. As an example, the area of the protruding portion PP may be larger than or smaller than the area of the dented portion DP. As an example, the first part 161a may have an area different from (e.g., lager than or smaller than) that of the virtual polygon VL, without being limited thereto.

The first part 161a may be enclosed by the second part 161b. The second part 161b is a part in which the first electrode 161 disposed on the top surface of the base portion 151 is covered by the bank 170. Referring to FIG. 2, the edge of the second part 161b is disposed to form a polygon on the plane. The second part 161b is disposed to have a polygonal shape having a plurality of sides on the plane.

In the meantime, on the plane, each edge of the second part 161b is disposed to have a portion parallel to the virtual polygon VL defined above. That is, each edge of the second part 161b is disposed so as to correspond to any one of the protruding portion PP or the dented portion DP.

Referring to FIG. 2, in the second part 161b, an area of a part corresponding to the protruding portion PP is smaller than an area corresponding to the dented portion DP. That is, the second part 161b may be disposed to have a portion in which an area is reduced as much as an area of the protruding portion PP and a portion in which an area is increased as much as an area of the dented portion DP on the plane.

The second part 161b may be a part corresponding to an area in which some of light emitted from the organic layer 162 in the sub-pixel SP reaches the bank 170 so that the light is not extracted to the outside of the display device 100. When the display device 100 is in an on-state, the area in the sub-pixel SP corresponding to the second part 161b may be a black state or have a luminance lower than that in the emission area.

The second part 161b may be enclosed by the third part 161c. The third part 161c is a part in which the first electrode 161 is disposed on the inclined surface of the protrusion 152. The third part 161c may correspond to an area in which some of light emitted from the organic layer 162 in the sub-pixel SP is reflected by the first electrode 161 disposed on the inclined surface of the protrusion 152 to be extracted to the outside of the display device 100.

In the meantime, referring to FIG. 2, the edges of the third part 161c are disposed to form a polygon on the plane. The third part 161c is disposed to have a polygonal shape having a plurality of sides on the plane. On the plane, each edge of the third part 161c is disposed to have a portion parallel to the edges of the virtual polygon VL defined above and the second part 161b. That is, each edge of the third part 161c is disposed so as to correspond to any one of the protruding portion PP or the dented portion DP. Embodiments are not limited thereto. As an example, the edges of the third part 161c may be disposed to form a shape other than polygon (e.g., circular) on the plane. As an example, the edges of the third part 161c may be disposed to have a portion not parallel to the edges of the virtual polygon VL defined above and the second part 161b, without being limited thereto.

Referring to FIGS. 3 and 4, the third part 161c includes a concave inclined portion 161c1 and a convex inclined portion 161c2.

The concave inclined portion 161cl is disposed so as to correspond to the protruding portion PP. As illustrated in FIG. 3, the farther from the top surface of the protrusion 152, the smaller the inclination angle of the concave inclined portion 161c1.

The convex inclined portion 161c2 is disposed so as to correspond to the dented portion DP. As illustrated in FIG. 4, the farther from the top surface of the protrusion 152, the larger the inclination angle of the convex inclined portion 161c2.

In the meantime, referring to FIGS. 3 and 4, a volume of the bank 170 disposed on the concave inclined portion 161c1 is larger than a volume of the bank 170 disposed on the convex inclined portion 161c2. That is, a path of light emitted from the organic layer 162 to reach the concave inclined portion 161c1 may be longer than a path of light to reach the convex inclined portion 161c2.

The third part 161c may be enclosed by the fourth part 161d. The fourth part 161d is a part in which the first electrode 161 is disposed on a part of the flat top surface of the protrusion 152. When the display device 100 is in an on-state, the fourth part 161d is in a black state in the sub-pixel SP or has a luminance lower than that in an emission area due to the light incident from the emission area, but is not limited thereto.

As an example, the fourth part 161d may be an area in which components for driving the light emitting diode 160 are disposed, without being limited thereto. For example, in the fourth part 161d of the first electrode 161, a contact hole through which the first electrode 161 and the transistor 120 are connected may be disposed, but is not limited thereto. As an example, a contact hole through which the first electrode 161 and the transistor 120 are connected may be disposed in the fourth part 161d. As an example, components for driving the light emitting diode 160 may overlap or may not overlap the fourth part 161d. As an example, the fourth part 161d may have a width smaller than, equal to or greater than that of at least one of or each of the third part 161c, the second part 161b and the first part 161a, without being limited thereto. As an example, the fourth part 161d may be omitted depending on the design.

Even though in FIG. 3, the first electrode 161 is illustrated as a single layer, the first electrode 161 may be configured as a multiple layer. For example, the first electrode 161 may include a reflective layer which reflects light emitted from the organic layer 162 toward the second electrode 163 and a transparent conductive layer which supplies holes to the organic layer 162, without being limited thereto. As an example, the first part 161a, the second part 161b, the third part 161c and the fourth part 161d may have the same layer or different layers. As an example, the first part 161a may have the reflective layer and the transparent conductive layer, while the third part 161c may have only the reflective layer, without being limited thereto.

The reflective layer is disposed on the second over coating layer 150 to reflect light emitted from the light emitting diode 160 upwardly. The light generated in the organic layer 162 of the light emitting diode 160 may be emitted not only upwardly, but also laterally and downwardly. The light which is laterally or downwardly emitted is directed to the inside of the display device 100 or trapped in the display device 100 due to the total reflection, or further travels to the inside of the display device 100 and then disappears. Therefore, the reflective layer is disposed below the organic layer 162 to cover a side portion of the plurality of protrusions 152 to change a traveling direction of the light which is directed to a side portion of the organic layer 162 to a front surface direction.

As an example, the reflective layer may be formed of a metal material such as aluminum (Al), silver (Ag), copper (Cu), and a magnesium-silver alloy (Mg:Ag), but is not limited thereto.

The transparent conductive layer is disposed on the reflective layer. The transparent conductive layer may be formed of a conductive material having a high work function to supply holes to the organic layer 162, without being limited thereto. For example, the transparent conductive layer may be formed of transparent conductive oxide such as indium tin oxide (ITO), indium zinc oxide (IZO), indium tin zinc oxide (ITZO), zinc oxide (ZnO), and tin oxide (TO), but is not limited thereto.

The bank 170 may be formed of an inorganic material. For example, the bank 170 may be formed of a single layer of silicon nitride (SiNx) or silicon oxide (SiOx) or a multiple layer of silicon nitride (SiNx) and silicon oxide (SiOx). However, it is not limited thereto and the bank 170 may be formed of an organic material.

The organic layer 162 is disposed on the first electrode 161. As an example, the organic layer 162 may be further disposed on the bank 170, without being limited thereto. For example, the organic layer 162 is disposed on the first electrode 161 in the emission area and is disposed on the bank 170 in the non-emission area. The organic layer 162 may be disposed along the shapes of the first electrode 161 and the bank 170. The organic layer 162 includes an emission layer or may further include a common layer, without being limited thereto.

The emission layer is an organic layer which emits light with a specific color. Different emission layers may be disposed in the plurality of sub-pixels SP, respectively or the same emission layer may be disposed in all the plurality of sub-pixels SP. For example, when different emission layers are disposed in the plurality of sub-pixels SP, respectively, a red emission layer may be disposed in a red sub-pixel SPR, a green emission layer may be disposed in the green sub-pixel SPG, and a blue emission layer may be disposed in the blue sub-pixel SPB. When the same emission layer is disposed in all the plurality of sub-pixels SP, light from the emission layer may be converted to various color light through a separate light conversion layer, a color filter, and the like.

As an example, the common layer is an organic layer which is disposed to improve the luminous efficiency of the emission layer, without being limited thereto. The common layer may be formed as the same layer over the plurality of sub-pixels SP. That is, the common layers of the plurality of sub-pixels SP may be simultaneously formed with the same material by the same process. The common layer may include a hole injection layer, a hole transport layer, an electron transport layer, an electron injection layer, and/or a charge generation layer, but is not limited thereto.

Alternatively, the organic layer 162 may be configured by laminating a plurality of light emitting units each of which includes emission layers and is configured to emit light, respectively. For example, each light emitting unit includes a hole injection layer, a hole transport layer, an emission layer, an electron transport layer, and an electron injection layer and a charge generation layer which supplies charges to the plurality of light emitting units is disposed between the adjacent light emitting units. Therefore, in the organic layer 162, light in which light emitted from each of the plurality of light emitting units is mixed may be emitted, but is not limited thereto. As an example, at least in some of the plurality of light emitting units, at least one of the hole injection layer, the hole transport layer, the electron transport layer, and the electron injection layer may be omitted.

The second electrode 163 is disposed on the organic layer 162. The second electrode 163 may be disposed along the shape of the organic layer 162. The second electrode 163 supplies electrons to the organic layer 162 so that the second electrode may be formed of a conductive material having a low work function, without being limited thereto. The second electrode 163 may be a cathode of the light emitting diode 160. The second electrode 163 may be formed of a transparent conductive material such as indium tin oxide (ITO) or indium zinc oxide (IZO), or a metal alloy such as MgAg or a ytterbium (Yb) alloy and may further include a metal doping layer, but is not limited thereto. In the meantime, even though it is not illustrated in the drawing, the second electrode 163 is electrically connected to a low potential power line to be supplied with a low potential power signal.

An encapsulation unit 180 may be formed on the light emitting diode 160 to protect the light emitting diode 160 which is vulnerable to moisture so as not to be exposed to the moisture. The encapsulation unit 180 may block the oxygen and moisture which penetrate into the light emitting display device 100 from the outside. For example, when the light emitting display device 100 is exposed to the moisture or oxygen, a pixel shrink phenomenon that the emission area is shrunk may occur or a dead pixel in the emission area may be generated. Therefore, the encapsulation unit 180 blocks the oxygen and moisture to protect the light emitting display device 100. For example, the encapsulation unit 180 may have a structure in which inorganic layers and organic layers are alternately laminated, but is not limited thereto.

Referring to FIGS. 3 and 4, as an example, the encapsulation unit 180 may include a first encapsulation layer 181, a foreign material cover layer 182, and a second encapsulation layer 183, without being limited thereto. As an example, the encapsulation unit 180 may include less than three layers or more than three layers.

The first encapsulation layer 181 is disposed on the second electrode 163 to suppress the permeation of the moisture or oxygen. The first encapsulation layer 181 may be formed of an inorganic material such as silicon nitride (SiNx), silicon oxynitride (SiNxOy), or aluminum oxide (AlyOz), but is not limited thereto. As an example, the first encapsulation layer 181 may be formed of a material having a refractive index higher than that of the foreign material cover layer 182, but is not limited thereto.

The foreign material cover layer 182 is disposed on the first encapsulation layer 181, for example, to planarize the surface. Further, the foreign material cover layer 182 may cover foreign materials or particles which may be generated during a manufacturing process. The foreign material cover layer 182 may be formed of an organic material, such as silicon oxy carbon (SiOxCz), acryl or epoxy resin, but is not limited thereto.

The second encapsulation layer 183 is disposed on the foreign material cover layer 182 and may suppress the permeation of the moisture or oxygen, like the first encapsulation layer 181. The second encapsulation layer 183 may be formed of an inorganic material such as silicon nitride (SiNx), silicon oxynitride (SiNxOy), silicon oxide (SiOx), or aluminum oxide (AlyOz), but is not limited thereto. The second encapsulation layer 183 may be formed of the same material as the first encapsulation layer 181 or formed of a different material from the first encapsulation layer 181.

In the display device using a first electrode formed on an over coating layer having a flat top surface, light which is emitted at a low emission angle, among light emitted from the organic layer is lost due to being trapped in the light emitting display device due to total reflection loss or light waveguide loss to cause the degradation of the luminous efficiency. Therefore, an over coating layer having a protrusion is used and the first electrode is disposed on the inclined side surface of the protrusion to reflect light emitted from the organic layer and extract the light to the outside of the display device, thereby improving the light extraction efficiency of the light emitting diode.

In the meantime, in the emission area in which the first electrode is exposed from the bank, the luminous efficiency may be concentrated in a boundary area of the emission area and the bank. Therefore, in order to increase the length of the boundary area of the emission area and the bank, a size of the emission area also needs to be expanded. However, due to the resolution of the display device and a constraint of the placement space, the size of the emission area needs to be expanded in a limited space.

In the display device 100 according to the example embodiment of the present disclosure, a protruding portion PP and a dented portion DP are disposed in the first part 161a of the first electrode 161 so that the light extraction efficiency may be increased while maintaining the area of the emission area.

Specifically, the first part 161a corresponding to an emission area in which some of light emitted from the organic layer 162 in the sub-pixel SP is extracted to the outside of the display device 100 via the organic layer 162 and the second electrode 163 includes the protruding portion PP and the dented portion DP. The protruding portion PP is a portion extended toward the outside of the first part 161a on the plane and the dented portion DP is a portion dented toward the inside of the first part 161a on the plane. As an example, the area of the protruding portion PP and the area of the dented portion DP may be equal to each other so that the first part 161a may be configured to be extended or dented with the same area on the plane. Therefore, the length of the edge of the first part 161a may be further increased for the same area. As an example, the emission area corresponding to the first part 161a may be configured to increase only the length of the edge without increasing the area. Therefore, the boundary area of the emission area and the bank in which the luminous efficiency is concentrated is also increased so that the light extraction efficiency may be improved without increasing the area of the emission area. Accordingly, in the display device 100 according to the example embodiment of the present disclosure, a protruding portion PP and a dented portion DP are disposed in the first part 161a of the first electrode 161 so that the light extraction efficiency may be increased while maintaining the area of the emission area. Although it is described that the area of the protruding portion PP and the area of the dented portion DP may be equal to each other, embodiments are not limited thereto. As an example, the area of the protruding portion PP may be different from the area of the dented portion DP. Although it is illustrated that there are a plurality of protruding portions PP and a plurality of dented portions DP along the edge of the emission area, embodiments are not limited thereto. As an example, there could be only a plurality of protruding portions PP or only a plurality of dented portions DP along the edge of the emission area. As an example, there could be at least one protruding portion PP or at least one dented portion DP along the edge of the emission area. Although it is illustrated that the plurality of protruding portions PP or the plurality of dented portions DP are regularly distributed along the edge of the emission area, embodiments are not limited thereto. As an example, the plurality of protruding portions PP or the plurality of dented portions DP may be irregularly distributed along the edge of the emission area. Although it is illustrated that one protruding portion PP and one dented portion DP are alternately arranged, embodiments are not limited thereto. As an example, a plurality of protruding portions PP or a plurality of dented portions DP may be continuously arranged. Although it is illustrated that the protruding portion PP and the dented portion DP have a curved shape, embodiments are not limited thereto. As an example, the protruding portion PP or the dented portion DP may have an angular shape. Although it is illustrated that the plurality of protruding portions PP or the plurality of dented portions DP may have the same shape, they may also have varied shapes.

In the meantime, in the display device 100 according to the example embodiment of the present disclosure, a concave inclined portion 161c1 and a convex inclined portion 161c2 corresponding to the protruding portion PP and the dented portion DP, respectively, are disposed in the third part 161c of the first electrode 161. Therefore, at least some of the light reflected from the third part 161c corresponding to the protruding portion PP and light reflected from the third part 161c corresponding to the dented portion DP may be guided to the front surface direction.

Specifically, the second part 161b corresponding to the protruding portion PP is disposed to have a smaller area than that of the second part 161b corresponding to the dented portion DP. Therefore, a light path of light emitted from the organic layer 162 which passes through the second part 161b corresponding to the protruding portion PP may be shorter than a light path of the light which passes through the second part 161b corresponding to the dented portion DP. Accordingly, in the display device 100 according to the example embodiment of the present disclosure, the concave inclined portion 161cl is disposed in the third part 161c corresponding to the protruding portion PP and the convex inclined portion 161c2 is disposed in the third part 161c corresponding to the dented portion DP. Therefore, a volume of the bank 170 disposed on the concave inclined portion 161c1 is larger than a volume of the bank 170 disposed on the convex inclined portion 161c2. Therefore, the light path of light emitted from the organic layer 162 to reach the concave inclined portion 161c1 may be less shorter than, or may be equal to or even longer than the light path to reach the convex inclined portion 161c2. Therefore, the concave inclined portion 161cl and the convex inclined portion 161c2 may be disposed to compensate for a length difference of a light path which passes through the second part 161b corresponding to the protruding portion PP and a light path which passes through the second part 161b corresponding to the dented portion DP. Accordingly, in the display device 100 according to the example embodiment of the present disclosure, in the third part 161c of the first electrode 161, a concave inclined portion 161c1 and a convex inclined portion 161c2 corresponding to the protruding portion PP and the dented portion DP, respectively, are disposed. Therefore, all light reflected from the third part 161c corresponding to the protruding portion PP and light reflected from the third part 161c corresponding to the dented portion DP may be guided to the front surface direction. Embodiments are not limited thereto. As an example, a flat inclined portion may be disposed in one or both of the third part 161c corresponding to the protruding portion PP and the third part 161c corresponding to the dented portion DP. As an example, a concave inclined portion or a convex inclined portion may be disposed in both of the third part 161c corresponding to the protruding portion PP and the third part 161c corresponding to the dented portion DP. As an example, the inclined portion disposed in the third part 161c corresponding to the protruding portion PP may be more concave than the inclined portion disposed in the third part 161c corresponding to the dented portion DP, without being limited thereto.

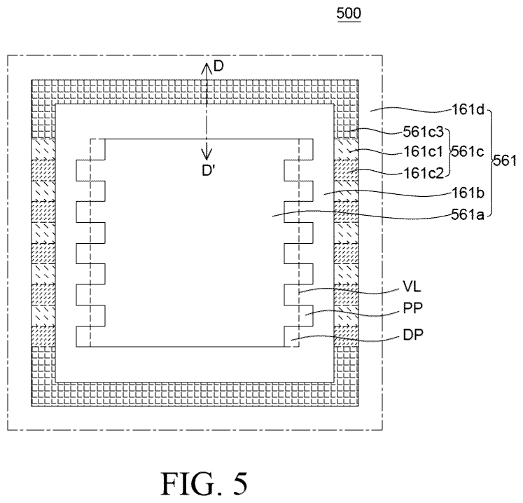

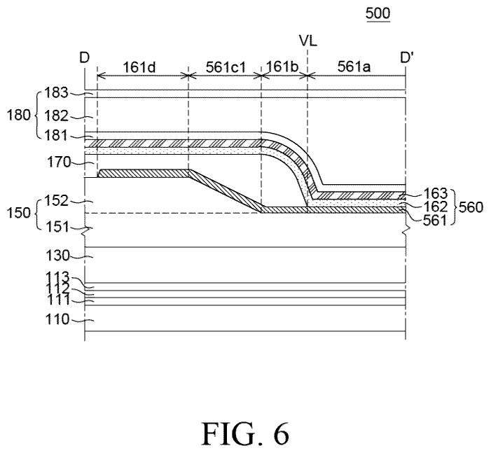

FIG. 5 is a plan view of a display device according to another example embodiment of the present disclosure. FIG. 6 is a cross-sectional view of a display device taken along line D-D′ of FIG. 5. For the convenience of description, in FIG. 5, only a first electrode 561 disposed in one sub-pixel SP, among various components of a display device 500 is illustrated and the fourth part 161d of the first electrode 561 is omitted. FIG. 6 is a cross-sectional view for an area in which a flat inclined portion 561c3 of the first electrode 561 is disposed. In the meantime, in FIG. 5, for the convenience of description, the concave inclined portion 161c1, the convex inclined portion 161c2, and the flat inclined portion 561c3 are illustrated with different hatchings. However, the concave inclined portion 161c1, the convex inclined portion 161c2, and the flat inclined portion 561c3 may be integrally disposed using the same material, but they are not limited thereto. The only difference between the display device 500 of FIG. 5 and the display device 100 of FIGS. 1 to 4 is the shape of the first part 561a and the placement of the flat inclined portion 561c3, but the other configuration is substantially the same, so that a redundant description will be omitted or briefly given.

Referring to FIG. 5, on the plane, a protruding portion PP and a dented portion DP are not disposed in a part of the edge of the first part 561a. That is, the first part 561a may have a portion overlapping the virtual polygon VL which has been described above, on the plane. For example, the planar shape of the first part 561a may be a shape including square saw teeth as illustrated in FIG. 5, but is not limited thereto.

Referring to FIGS. 5 and 6, in the display device 500 according to another example embodiment of the present disclosure, the third part 561c of the first electrode 561 of the light emitting diode 560 may further include a flat inclined portion 561c3.

The flat inclined portion 561c3 is a portion disposed so as to correspond to an edge of the first part 561a on which the protruding portion PP and the dented portion DP are not disposed. The flat inclined portion 561c3 is disposed to have a flat inclined surface.

In the meantime, referring to FIGS. 3, 4, and 6 again, a volume of the bank 170 disposed on the flat inclined portion 561c3 is smaller than a volume of the bank 170 disposed on the concave inclined portion 161c1 and is larger than a volume of the bank 170 disposed on the convex inclined portion 161c2. As an example, a light path of light emitted from the organic layer 162 to reach the flat inclined portion 561c3 may be shorter than a light path to reach the concave inclined portion 161c1. As an example, a light path of light emitted from the organic layer 162 to reach the flat inclined portion 561c3 may be longer than a light path to reach the convex inclined portion 161c2. Embodiments are not limited thereto. As an example, a light path of light emitted from the organic layer 162 to reach the flat inclined portion 561c3 may be less longer than, equal to or even shorter than a light path to reach the concave inclined portion 161c1, without being limited thereto. As an example, a light path of light emitted from the organic layer 162 to reach the flat inclined portion 561c3 may be less shorter than, equal to or even longer than a light path to reach the convex inclined portion 161c2, without being limited thereto.

Accordingly, in the display device 500 according to another example embodiment of the present disclosure, in the third part 561c of the first electrode 561, the concave inclined portion 161c1, the convex inclined portion 161c2, and the flat inclined portion 561c3 corresponding to the protruding portion PP, the dented portion DP, and a portion in which the protruding portion PP and the dented portion DP are not disposed, respectively, are disposed. Therefore, all light reflected from the third part 161c corresponding to the protruding portion PP, light reflected from the third part 561c corresponding to the dented portion DP, and light reflected from the third part 561c corresponding to the portion in which the protruding portion PP and the dented portion DP are not disposed may be guided to the front surface direction.

Specifically, the second part 161b corresponding to the protruding portion PP is disposed to have a smaller area than that of the second part 161b corresponding to the dented portion DP. The second part 161b corresponding to the portion in which the protruding portion PP and the dented portion DP are not disposed is disposed to have a larger area than that of the second part 161b corresponding to the protruding portion PP and is disposed to have a smaller area than that of the second part 161b corresponding to the dented portion DP. Therefore, light path of light emitted from the organic layer 162 to pass through the second part 161b corresponding to the protruding portion PP may be shorter than the light path to pass through the second part 161b corresponding to the dented portion DP. Further, the light path to pass through the second part 161b corresponding to the portion in which the protruding portion PP and the dented portion DP are not disposed may be longer than the light path to pass through the second part 161b corresponding to the protruding portion PP and may be shorter than the light path to pass through the second part 161b corresponding to the dented portion DP. Accordingly, in the display device 500 according to another example embodiment of the present disclosure, the concave inclined portion 161cl is disposed in the third part 561c corresponding to the protruding portion PP and the convex inclined portion 161c is disposed in the third part 561c corresponding to the dented portion DP. Therefore, the flat inclined portion 561c3 is disposed in the third part 561c corresponding to the portion in which the protruding portion PP and the dented portion DP are not disposed. Therefore, a volume of the bank 170 disposed on the concave inclined portion 161c1 is larger than a volume of the bank 170 disposed on the convex inclined portion 161c2. Therefore, the light path of light emitted from the organic layer 162 to reach the concave inclined portion 161c1 may be less shorter than, equal to or even longer than the light path to reach the convex inclined portion 161c2. Further, a light path of light emitted from the organic layer 162 to reach the flat inclined portion 561c3 may be less longer than, equal to or even shorter than a light path to reach the concave inclined portion 161c1 and may be less shorter than, equal to or even longer than a light path to reach the convex inclined portion 161c2. Therefore, the concave inclined portion 161c1, the convex inclined portion 161c2, and the flat inclined portion 561c3 may be disposed to compensate for a length difference of a light path which passes through the second part 161b corresponding to the protruding portion PP, a light path which passes through the second part 161b corresponding to the dented portion DP, and a light path which passes through the second part 161b corresponding to the portion in which the protruding portion PP and the dented portion DP are not disposed. Accordingly, in the third part 561c of the first electrode 561, the concave inclined portion 161c1, the convex inclined portion 161c2, and the flat inclined portion 561c3 corresponding to the protruding portion PP, the dented portion DP, and a portion in which the protruding portion PP and the dented portion DP are not disposed, respectively, are disposed. Therefore, all light reflected from the third part 161c corresponding to the protruding portion PP, light reflected from the third part 561c corresponding to the dented portion DP, and light reflected from the third part 561c corresponding to the portion in which the protruding portion PP and the dented portion DP are not disposed may be guided to the front surface direction.

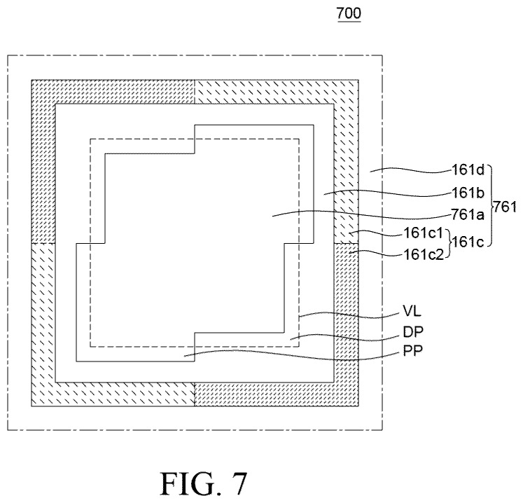

Hereinafter, various shapes which may be used for a planar shape of the first part will be introduced with reference to FIGS. 7 to 9.

FIG. 7 is a plan view of a display device according to still another example embodiment of the present disclosure. For the convenience of description, in FIG. 7, only a first electrode 761 disposed in one sub-pixel SP, among various components of a display device 700 is illustrated and the fourth part 161d of the first electrode 761 is omitted. The only difference between a display device 700 of FIG. 7 and the display device 100 of FIGS. 1 to 4 is a shape of a first part 761a, but the other configuration is the same or similar, so that a redundant description will be omitted or briefly given.

Referring to FIG. 7, in the display device 700 according to still another example embodiment of the present disclosure, a first part 761a of a first electrode 761 may include a protruding portion PP and a dented portion DP.

The protruding portion PP is a portion whose area is increased toward the outside of the first part 761a on the plane and the dented portion DP is a portion whose area is decreased to the inside of the first part 761a on the plane. As an example, an area of the protruding portion PP and an area of the dented portion DP may be equal to each other, without being limited thereto. That is, the first part 761a is disposed to have a portion whose area is inwardly reduced, with the same area as the portion whose area is outwardly increased on the plane. For example, the planar shape of the first part 761a may be a leaf shape as illustrated in FIG. 7, but is not limited thereto. As an example, the first part 761a may only include one of the protruding portion PP and the dented portion DP. As an example, an area of the protruding portion PP and an area of the dented portion DP may be different from each other, without being limited thereto.

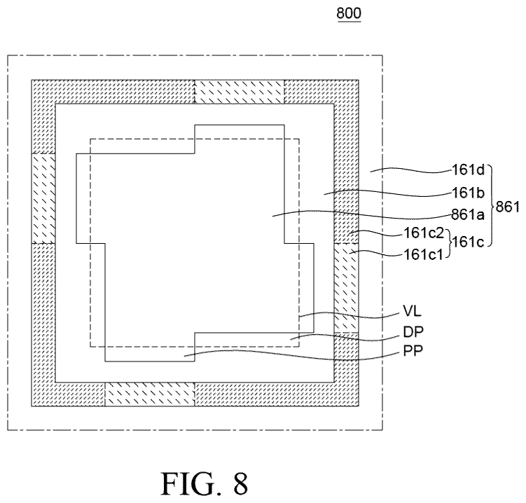

FIG. 8 is a plan view of a display device according to still another example embodiment of the present disclosure. For the convenience of description, in FIG. 8, only a first electrode 861 disposed in one sub-pixel SP, among various components of a display device 800 is illustrated and the fourth part 161d of the first electrode 861 is omitted. The only difference between a display device 800 of FIG. 8 and the display device 100 of FIGS. 1 to 4 is a shape of a first part 861a, but the other configuration is the same or similar, so that a redundant description will be omitted or briefly given.

Referring to FIG. 8, in the display device 800 according to still another example embodiment of the present disclosure, a first part 861a of a first electrode 861 may include a protruding portion PP and a dented portion DP.

The protruding portion PP is a portion whose area is increased toward the outside of the first part 861a on the plane and the dented portion DP is a portion whose area is decreased toward the inside of the first part 861a on the plane. As an example, an area of the protruding portion PP and an area of the dented portion DP may be equal to each other, without being limited thereto. That is, the first part 861a is disposed to have a portion whose area is inwardly reduced, with the same area as the portion whose area is outwardly increased on the plane. For example, the planar shape of the first part 861a may be a windmill shape as illustrated in FIG. 8, but is not limited thereto. As an example, the first part 861a may only include one of the protruding portion PP and the dented portion DP. As an example, an area of the protruding portion PP and an area of the dented portion DP may be different from each other, without being limited thereto.

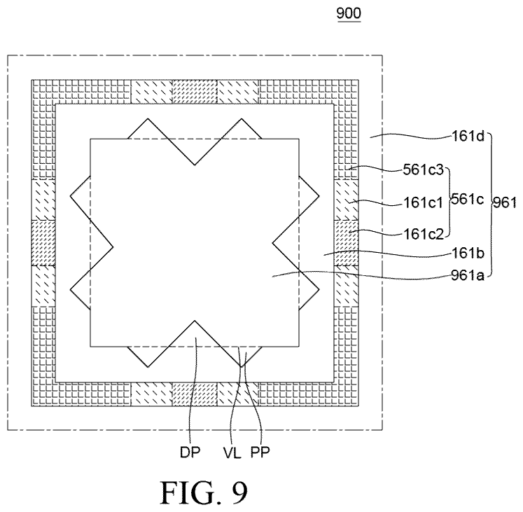

FIG. 9 is a plan view of a display device according to still another example embodiment of the present disclosure. For the convenience of description, in FIG. 9, only a first electrode 961 disposed in one sub-pixel SP, among various components of a display device 900 is illustrated and the fourth part 161d of the first electrode 961 is omitted. The only difference between a display device 900 of FIG. 9 and the display device 500 of FIGS. 5 and 6 is a shape of a first part 961a, but the other configuration is the same or similar, so that a redundant description will be omitted or briefly given.

Referring to FIG. 9, in the display device 900 according to still another example embodiment of the present disclosure, a first part 961a of a first electrode 961 may include a protruding portion PP and a dented portion DP.

The protruding portion PP is a portion whose area is increased to the outside of the first part 961a on the plane and the dented portion DP is a portion whose area is decreased to the inside of the first part 961a on the plane. As an example, an area of the protruding portion PP and an area of the dented portion DP may be equal to each other, without being limited thereto. That is, the first part 961a is disposed to have a portion in which the area is inwardly reduced, with the same area as the portion whose area is outwardly increased on the plane. For example, the planar shape of the first part 961a may be a flower shape as illustrated in FIG. 9, but is not limited thereto. As an example, the first part 961a may only include one of the protruding portion PP and the dented portion DP. As an example, an area of the protruding portion PP and an area of the dented portion DP may be different from each other, without being limited thereto.

The example embodiments of the present disclosure can also be described as follows:

According to an aspect of the present disclosure, a display device includes a substrate, a plurality of sub-pixels, an over coating layer which is disposed on the substrate and includes a base portion and a protrusion which is disposed on the base portion and has an inclined side surface; an anode which is disposed so as to correspond to each of the plurality of sub-pixels and cover parts of the base portion and the protrusion; and a bank disposed on a part of the anode. The anode includes a first part which is disposed on a top surface of the base portion and is exposed from the bank; a second part which is disposed on the top surface of the base portion and is covered by the bank; and a third part disposed on a side surface of the protrusion, an edge of the second part forms a first polygon on the plane. When a virtual second polygon which is congruent with the first polygon while sharing the center with the first polygon and is disposed with a smaller area than the first polygon on the plane is defined, the first part includes a protruding portion which is formed by an edge disposed at the outside more than the second polygon on the plane and a dented portion which is formed by an edge disposed inside more than the second polygon on the plane, an area of the protruding portion and an area of the dented portion are equal to each other on the plane, and the third part includes a concave inclined portion which corresponds to the protruding portion and has a concave inclined surface and a convex inclined portion which corresponds to the dented portion and has a convex inclined surface.

The protruding portion may be a portion which is disposed to increase an area to an outside of the first part on the plane and the dented portion may be a portion which is disposed to decrease an area to an inside of the first part on the plane.

An area of the second part corresponding to the protruding portion may be smaller than an area of the second part corresponding to the dented portion.

A volume of a bank disposed on the concave inclined portion may be larger than a volume of a bank disposed on the convex inclined portion.

The third part may further include a flat inclined portion corresponding to an edge which overlaps an edge of the second polygon on the plane, among edges of the first part.

A volume of a bank disposed on the flat inclined portion may be smaller than a volume of a bank disposed on the concave inclined portion, and may be larger than a volume of a bank disposed on the convex inclined portion.

The protruding portion and the dented portion may not be disposed in the first part which is opposite to the flat inclined portion.

The farther from a top surface of the protruding portion, the smaller an inclination angle of the concave inclined portion may be.

The farther from a top surface of the protruding portion, the larger an inclination angle of the convex inclined portion may be.

On the plane, each edge of the first polygon may have a part parallel to an edge of the second polygon.

The anode may further include a fourth part which extends from the third part to be disposed on a part of a top surface of the protruding portion.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the appended claims, and all the technical concepts in the equivalent scope thereof should be construed as falling within the scope of the present disclosure.

What is claimed is:

1. A display device, comprising:
a substrate;
a plurality of sub-pixels;
an over coating layer which is disposed on the substrate;
an anode which is disposed on the over coating layer so as to correspond to each of the plurality of sub-pixels; and
a bank disposed on a part of the anode,
wherein the anode includes:
a first part which is disposed on a top surface of the over coating layer and is exposed from the bank; and
a second part which extends from the first part, is disposed on the top surface of the over coating layer and is covered by the bank, and
wherein an edge of the first part includes at least one protruding portion protruding toward the second part.

2. The display device according to claim 1, wherein the edge of the first part further includes at least one dented portion dented inside the first part.

3. The display device according to claim 2, wherein the protruding portion and the dented portion are alternately arranged along at least a portion of the edge of the first part.

4. The display device according to claim 3, wherein the at least a portion of the edge of the first part has a planar shape including circular saw teeth or square saw teeth.

5. The display device according to claim 2, wherein, with respect to a reference line from which the protruding portion protrudes and the dented portion is dented, an area of the protruding portion and an area of the dented portion are equal to each other on a plane.

6. The display device according to claim 2, wherein the protruding portion and the dented portion are not disposed in a portion of the edge of the first part, said portion of the edge overlapping a reference line from which the protruding portion protrudes and the dented portion is dented.

7. The display device according to claim 2, wherein the over coating layer includes a base portion and a protrusion which is disposed on the base portion and has an inclined side surface toward the first part and the second part, the first part and the second part being disposed on a top surface of the base portion.

8. The display device according to claim 7, wherein the anode further includes a third part which extends from the second part and is disposed on the inclined side surface of the protrusion.

9. The display device according to claim 8, wherein the third part includes a concave inclined portion which corresponds to the protruding portion and has a concave inclined surface and a convex inclined portion which corresponds to the dented portion and has a convex inclined surface.

10. The display device according to claim 9, wherein the third part further includes a flat inclined which corresponds to a portion of the edge of the first part in which the protruding portion and the dented portion are not disposed.

11. The display device according to claim 9, wherein the bank further covers the third part, and
wherein a light path of light for being emitted from an organic layer disposed on the first part to reach the concave inclined portion has a same length as a light path of light for being emitted from the organic layer to reach the convex inclined portion.

12. The display device according to claim 8, wherein the third part includes a reflective layer for reflecting light emitted from an organic layer disposed on the first part.

13. The display device according to claim 8, wherein an inclined portion of the third part which corresponds to the protruding portion is more concave downward than an inclined portion of the third part which corresponds to the dented portion.

14. The display device according to claim 1, wherein an edge of the second part forms a first polygon on a plane, and when a virtual second polygon which is congruent with the first polygon while sharing a center with the first polygon and is disposed with a smaller area than the first polygon on the plane is defined, the first part includes the protruding portion which is formed by an edge disposed outside of the virtual second polygon on the plane and a dented portion which is formed by an edge disposed inside of the virtual second polygon.

15. The display device according to claim 14, wherein an area of the protruding portion and an area of the dented portion are equal to each other on the plane.

16. The display device according to claim 14, wherein the over coating layer includes a base portion and a protrusion which is disposed on the base portion and has an inclined side surface toward the first part and the second part, the anode covers the base portion and a part of the protrusion, and the first part and the second part are disposed on a top surface of the base portion, and
wherein the anode further includes a third part disposed on the inclined side surface of the protrusion, and the third part includes a concave inclined portion which corresponds to the protruding portion and has a concave inclined surface and a convex inclined portion which corresponds to the dented portion and has a convex inclined surface.

17. The display device according to claim 16, wherein the protruding portion is a portion which is extended to an outside of the first part on the plane and the dented portion is a portion which is dented to an inside of the first part on the plane.

18. The display device according to claim 16, wherein an area of the second part corresponding to the protruding portion is smaller than an area of the second part corresponding to the dented portion.

19. The display device according to claim 18, wherein a volume of a bank disposed on the concave inclined portion is larger than a volume of a bank disposed on the convex inclined portion.

20. The display device according to claim 16, wherein the third part further includes a flat inclined portion corresponding to an edge which overlaps an edge of the virtual second polygon on the plane, among edges of the first part.

21. The display device according to claim 20, wherein a volume of a bank disposed on the flat inclined portion is smaller than a volume of a bank disposed on the concave inclined portion, and is larger than a volume of a bank disposed on the convex inclined portion.

22. The display device according to claim 20, wherein the protruding portion and the dented portion are not disposed in a portion of the edge of the first part corresponding to the flat inclined portion.

23. The display device according to claim 16, wherein the farther from a top surface of the protruding portion, the smaller an inclination angle of the concave inclined portion.

24. The display device according to claim 16, wherein the farther from a top surface of the protruding portion, the larger an inclination angle of the convex inclined portion.

25. The display device according to claim 16, wherein on the plane, each edge of the first polygon has a part parallel to an edge of the virtual second polygon.

26. The display device according to claim 16, wherein the anode further includes a fourth part which extends from the third part to be disposed on a part of a top surface of the protruding portion.
